(19) United States
(12) Patent Application Publication
(10) Pub. No.: US 2025/0373270 A1
(43) Pub. Date: Dec. 4, 2025

(54) RADIO FREQUENCY CIRCUIT AND COMMUNICATION DEVICE

(71) Applicant: Murata Manufacturing Co., Ltd., Nagaokakyo-shi (JP)

(72) Inventors: Hirotsugu MORI, Nagaokakyo-shi (JP); Atsushi HORITA, Nagaokakyo-shi (JP)

(73) Assignee: Murata Manufacturing Co., Ltd., Nagaokakyo-shi (JP)

(21) Appl. No.: 19/298,197

(22) Filed: Aug. 13, 2025

Related U.S. Application Data
(63) Continuation of application No. PCT/JP2024/002880, filed on Jan. 30, 2024.

(30) Foreign Application Priority Data
Feb. 16, 2023 (JP) 2023-022823

(51) Int. Cl. H04B 1/00; H03H 7/46; H03H 9/00; H03H 9/25

(52) U.S. Cl. CPC H04B 1/0057; H03H 7/46; H03H 9/0014; H03H 9/25

(57) ABSTRACT

A radio frequency circuit includes a first filter having a first passband including downlink bands of first and second bands. The downlink band of the second band at least partially overlaps the downlink band of the first band. The low-frequency edge of the downlink band of the second band is lower than the low-frequency edge of the downlink band of the first band. The low-frequency edge of a first guard band defined on the lower frequency side of the downlink band of the first band, for the downlink band of the first band, coincides with the low-frequency edge of a second guard band defined on the lower frequency side of the downlink band of the second band, for the downlink band of the second band. The first filter has a higher attenuation steepness on the lower frequency side of the first passband than on the higher frequency side.

### CROSS-REFERENCE TO RELATED APPLICATIONS

This is a continuation application of PCT International Application No. PCT/JP2024/002880 filed on Jan. 30, 2024, designating the United States of America, which is based on and claims priority of Japanese Patent Application No. 2023-022823 filed on Feb. 16, 2023. The entire disclosures of the above-identified applications, including the specifications, drawings, and claims are incorporated herein by reference in their entirety.

### TECHNICAL FIELD

The present disclosure relates to a radio frequency circuit and a communication device.

### BACKGROUND

Mobile communication devices such as mobile phones increasingly operate on many frequency bands (“multi-band”). This requires their front-end circuits to become larger. U.S. Patent Application Publication No. 2015/0133067 discloses a radio frequency circuit that includes a plurality of filters for a plurality of frequency bands.

### SUMMARY

### Technical Problems

However, as conventional radio frequency circuits incorporate multi-band functionality, they inevitably require an increased number of filters.

In view of this, the present disclosure provides a radio frequency circuit and a communication device that can inhibit an increase in the number of filters required for multi-band functionality.

### Solutions

A radio frequency circuit according to one aspect of the present disclosure includes a first filter having a first passband that includes a downlink band of a first band and a downlink band of a second band. The downlink band of the second band at least partially overlaps the downlink band of the first band. A low-frequency edge of the downlink band of the second band is lower than a low-frequency edge of the downlink band of the first band. A low-frequency edge of a first guard band defined on a lower frequency side of the downlink band of the first band coincides with a low-frequency edge of a second guard band defined on a lower frequency side of the downlink band of the second band, the first guard band being for the downlink band of the first band, and the second guard band being for the downlink band of the second band. The first filter has a higher attenuation steepness on a lower frequency side of the first passband than on a higher frequency side of the first passband.

A radio frequency circuit according to one aspect of the present disclosure includes: a filter having a passband that includes a downlink band of Band 71 for LTE or n71 for 5G NR, and a downlink band of Band 105 for LTE or n105 for 5G NR. The filter has a higher attenuation steepness on a lower frequency side of the passband than on a higher frequency side of the passband.

A communication device according to one aspect of the present disclosure includes: a signal processing circuit configured to process a radio frequency signal; and the above-described radio frequency circuit configured to transfer the radio frequency signal between the signal processing circuit and an antenna.

### Advantageous Effects

A radio frequency circuit and a communication device according to one aspect of the present disclosure can inhibit an increase in the number of filters required for multi-band functionality.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 illustrates a circuit configuration of a communication device according to Embodiment 1.

FIG. 2 illustrates frequency bands related to Embodiment 1.

FIG. 3 illustrates a graph showing frequency characteristics of a filter according to Embodiment 1.

FIG. 4 illustrates a circuit configuration of a filter according to Embodiment 1.

FIG. 5A illustrates a cross-sectional view of a filter according to Embodiment 1.

FIG. 5B illustrates a cross-sectional view of a filter according to a variation of Embodiment 1.

FIG. 6 illustrates a circuit configuration of a communication device according to Embodiment 2.

FIG. 7 illustrates a circuit configuration of a communication device according to Embodiment 3.

### DESCRIPTION OF EMBODIMENTS

The following describes in detail embodiments of the present disclosure, with reference to the drawings. Note that the embodiments described below each show a general or specific example. The numerical values, shapes, materials, elements, and the arrangement and connection of the elements, for instance, described in the following embodiments are examples, and thus are not intended to limit the present disclosure.

Note that the drawings are schematic diagrams to which emphasis, omission, and ratio adjustment are appropriately added in order to illustrate the salient features of the present disclosure, and thus are not necessarily accurate or complete illustrations with respect to a commercial product. For example, the drawings may show shapes, positional relations, and ratios that are different from actual shapes, actual positional relations, and actual ratios. Throughout the drawings, the same numeral is given to substantially the same element, and redundant description may be omitted or simplified.

In the circuit configurations, being connected includes not only being directly connected by a connection terminal and/or a line conductor, but also being electrically connected via another circuit element. C being connected between A and B means that one end of C is connected to A and the other end of C is connected to B, and means that C is connected in series onto a path that connects A and B. A “terminal” means a point at which a conductor in an element ends. Note that under a condition that an impedance of a conductor between elements is sufficiently low, a terminal may be interpreted not only as a single fixed point, but as any point on the conductor between the elements or as the entire conductor.

Furthermore, a “passband of a filter” is a portion of a frequency spectrum of a signal transferred by a filter and is defined as a frequency band in which an output power is not attenuated from a maximum output power by 3 dB or more. Thus, a high-frequency edge and a low-frequency edge of a passband of a bandpass filter are identified as a higher frequency and a lower frequency at two points at which an output power is attenuated from a maximum output power by 3 dB.

The “attenuation steepness on the lower frequency side of a filter passband” is defined by the amount of gain reduction from the low-frequency edge of the filter passband to a frequency 4 MHz lower than the low-frequency edge. Thus, the “attenuation steepness on the lower frequency side of a filter passband” is represented by the difference between the gain at the low-frequency edge of the filter passband and the gain at a frequency 4 MHz lower than the low-frequency edge. Conversely, the “attenuation steepness on the higher frequency side of a filter passband” is defined by the amount of gain reduction from the high-frequency edge of the filter passband to a frequency 4 MHz higher than the high-frequency edge. Thus, the “attenuation steepness on the higher frequency side of a filter passband” is represented by the difference between the gain at the high-frequency edge of the filter passband and the gain at a frequency 4 MHz higher than the high-frequency edge. Such attenuation steepness is identified by removing the filter from the mounting substrate, mounting the filter alone on a dedicated test elementary group (TEG) substrate, and measuring its pass characteristics. Note that in a case in which the pass characteristics of the filter change when the filter is removed from the mounting substrate, the attenuation steepness can be identified by connecting probes to the input terminal and output terminal of the filter on the mounting substrate and measuring the pass characteristics of the filter.

A “downlink band” is a downlink operating band, and means a portion of a communication band that is designated for downlink communication. Thus, a “downlink band” means a band that is utilized to transfer radio frequency signals from a base station (BS) to a user equipment (UE) in frequency division duplex (FDD).

In contrast, an “uplink band” is an uplink operating band, and means a portion of a communication band that is designated for uplink communication. Thus, an “uplink band” means a band that is utilized to transfer radio frequency signals from a UE to a BS in FDD.

A “guard band” means an unused portion of the radio spectrum between two bands and/or channels that is provided to prevent interference between the two bands and/or channels.

A “band combination for simultaneous communication” means a plurality of bands predefined as a combination that can be used for simultaneous transmission, simultaneous reception, or simultaneous transmission and reception. The definition of “band combination for simultaneous communication” is made by standardizing bodies (such as the 3rd Generation Partnership Project (3GPP (registered trademark)) and the Institute of Electrical and Electronics Engineers (IEEE), for example). A “band combination for simultaneous communication” is defined as a band combination for carrier aggregation (CA), E-UTRAN New Radio-Dual Connectivity (EN-DC), New Radio-Dual Connectivity (NR-DC), or New Radio E-UTRAN-Dual Connectivity (NE-DC), for example.

### Embodiment 1

First, Embodiment 1 will be described. Communication device 5 according to the present embodiment functions as user equipment (UE) in a cellular network, and typically is a mobile phone, a smartphone, a tablet computer, or a wearable device, for instance. Note that communication device 5 may be an Internet of Things (IoT) sensor/device, a medical/health care device, a vehicle, an unmanned aerial vehicle (UAV) (also commonly referred to as a “drone”), or an automated guided vehicle (AGV). Furthermore, communication device 5 may function as a base station (BS) in the cellular network.

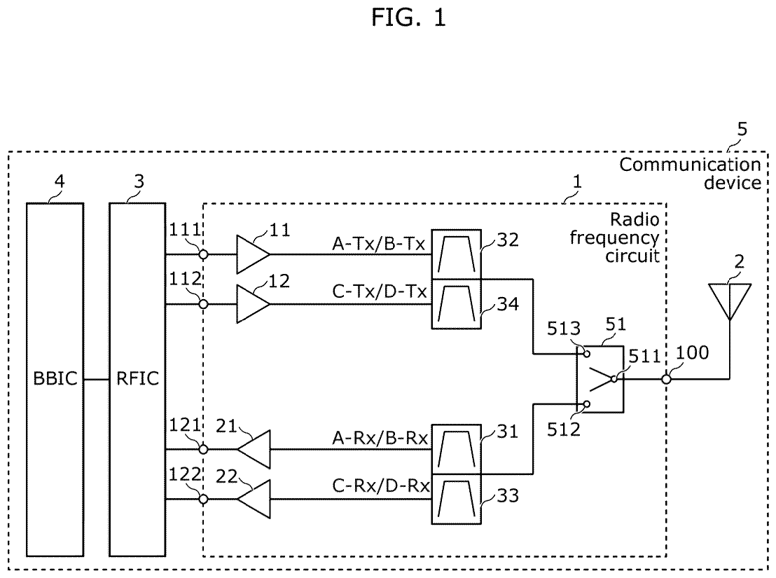

A circuit configuration of communication device 5 and radio frequency circuit 1 according to the present embodiment will be described with reference to FIG. 1. FIG. 1 illustrates a circuit configuration of communication device 5 according to the present embodiment.

Note that FIG. 1 illustrates an exemplary circuit configuration, and communication device 5 and radio frequency circuit 1 may be implemented using any of various types of circuit implementations and circuit technologies. Thus, the description of communication device 5 and radio frequency circuit 1 provided below should not be interpreted in a limited manner.

### [1.1 Circuit Configuration of Communication Device 5]

First, a circuit configuration of communication device 5 according to the present embodiment will be described with reference to FIG. 1. Communication device 5 is implemented in a UE, and includes radio frequency circuit 1, antenna 2, radio frequency integrated circuit (RFIC) 3, and baseband integrated circuit (BBIC) 4.

Radio frequency circuit 1 can transfer radio frequency signals between antenna 2 and RFIC 3. A circuit configuration of radio frequency circuit 1 will be described later.

Antenna 2 is connected to antenna connection terminal 100 of radio frequency circuit 1. Antenna 2 can receive radio frequency signals from the outside of communication device 5 and supply the radio frequency signals to radio frequency circuit 1. Furthermore, antenna 2 may transmit radio frequency signals supplied from radio frequency circuit 1 to the outside of communication device 5. Note that antenna 2 need not be included in communication device 5. Communication device 5 may further include one or more antennas in addition to antenna 2.

RFIC 3 is an example of a signal processing circuit that processes radio frequency signals. Specifically, RFIC 3 can process radio frequency received signals input through a reception path of radio frequency circuit 1 by down-conversion, for instance, and output received signals generated by processing the radio frequency received signals to BBIC 4. Furthermore, RFIC 3 may process transmission signals input from BBIC 4 by, for instance, up-conversion, and output radio frequency transmission signals generated by processing the transmission signals to radio frequency circuit 1. RFIC 3 may include a controller (e.g., programmable circuitry such as a CPU that is configured to perform control operations by the circuitry's execution of stored computer code) configured to control, for instance, a switch and a power amplifier that are included in radio frequency circuit 1. Note that the controller may be partially or entirely provided outside of RFIC 3. For example, the controller may be partially or entirely provided in BBIC 4 or radio frequency circuit 1.

BBIC 4 is a baseband signal processing circuit that processes signals using a frequency band lower than a frequency of a radio frequency signal transferred by radio frequency circuit 1. A signal processed by BBIC 4 is used, for example, as an image signal for image display or as an audio signal for voice through a loudspeaker. Note that BBIC 4 need not be included in communication device 5.

### [1.2 Circuit Configuration of Radio Frequency Circuit 1]

Next, a circuit configuration of radio frequency circuit 1 according to the present embodiment will be described with reference to FIG. 1. Radio frequency circuit 1 includes power amplifiers 11 and 12, low-noise amplifiers 21 and 22, filters 31 to 34, switch 51, antenna connection terminal 100, radio frequency input terminals 111 and 112, and radio frequency output terminals 121 and 122.

Antenna connection terminal 100 is an external connection terminal of radio frequency circuit 1. Specifically, antenna connection terminal 100 is connected to antenna 2 outside radio frequency circuit 1 and is connected to switch 51 inside radio frequency circuit 1. Accordingly, radio frequency circuit 1 can supply transmission signals to antenna 2 via antenna connection terminal 100, and can be supplied with received signals from antenna 2 via antenna connection terminal 100.

Radio frequency input terminals 111 and 112 are external connection terminals of radio frequency circuit 1. Specifically, radio frequency input terminal 111 is connected to RFIC 3 outside radio frequency circuit 1 and is connected to power amplifier 11 inside radio frequency circuit 1. Radio frequency input terminal 112 is connected to RFIC 3 outside radio frequency circuit 1 and is connected to power amplifier 12 inside radio frequency circuit 1. Radio frequency input terminal 111 can receive transmission signals in Bands A and B from RFIC 3, and radio frequency input terminal 112 can receive transmission signals in Bands C and D from RFIC 3.

Radio frequency output terminals 121 and 122 are external connection terminals of radio frequency circuit 1. Specifically, radio frequency output terminal 121 is connected to RFIC 3 outside radio frequency circuit 1 and is connected to low-noise amplifier 21 inside radio frequency circuit 1. Radio frequency output terminal 122 is connected to RFIC 3 outside radio frequency circuit 1 and is connected to low-noise amplifier 22 inside radio frequency circuit 1. Radio frequency output terminal 121 can supply received signals in Bands A and B to RFIC 3, and radio frequency output terminal 122 can supply received signals in Bands C and D to RFIC 3.

The input end of power amplifier 11 is connected to radio frequency input terminal 111. The output end of power amplifier 11 is connected to filter 32. Power amplifier 11 can amplify transmission signals in Bands A and B received via radio frequency input terminal 111, using power supplied from a power supply (not illustrated).

The input end of power amplifier 12 is connected to radio frequency input terminal 112. The output end of power amplifier 12 is connected to filter 34. Power amplifier 12 can amplify transmission signals in Bands C and D received via radio frequency input terminal 112, using power supplied from a power supply (not illustrated).

Power amplifiers 11 and 12 can include heterojunction bipolar transistors (HBTs), and can be manufactured using semiconductor material. As the semiconductor material, silicon-germanium (SiGe) or gallium arsenide (GaAs) can be used, for example. Note that amplifier transistors of power amplifiers 11 and 12 are not limited to HBTs. For example, at least one of power amplifier 11 or power amplifier 12 may include a high electron mobility transistor (HEMT) or a metal-semiconductor field effect transistor (MESFET). In this case, gallium nitride (GaN) or silicon carbide (SIC) may be used as the semiconductor material.

Note that power amplifier 11 and/or power amplifier 12 need not be partially or entirely included in radio frequency circuit 1. In this case, power amplifier 11 may be connected between RFIC 3 and radio frequency input terminal 111, and power amplifier 12 may be connected between RFIC 3 and radio frequency input terminal 112. Power amplifier 11 and/or power amplifier 12 may be partially or entirely included in RFIC 3.

The input end of low-noise amplifier 21 is connected to filter 31. The output end of low-noise amplifier 21 is connected to radio frequency output terminal 121. Low-noise amplifier 21 can amplify received signals in Bands A and B that have passed through filter 31, by using power supplied from a power supply (not illustrated).

The input end of low-noise amplifier 22 is connected to filter 33. The output end of low-noise amplifier 22 is connected to radio frequency output terminal 122. Low-noise amplifier 22 can amplify received signals in Bands C and D that have passed through filter 33, by using power supplied from a power supply (not illustrated).

Low-noise amplifiers 21 and 22 can include field effect transistors (FETs), and can be manufactured using a semiconductor material. As the semiconductor material, for example, monocrystalline silicon, GaN, or SiC can be used. Note that amplifier transistors of low-noise amplifiers 21 and 22 are not limited to FETs. For example, one or both of low-noise amplifiers 21 and 22 may each include a bipolar transistor.

Note that low-noise amplifiers 21 and 22 need not be partially or entirely included in radio frequency circuit 1. In this case, low-noise amplifier 21 may be connected between radio frequency output terminal 121 and RFIC 3, and low-noise amplifier 22 may be connected between radio frequency output terminal 122 and RFIC 3. One or both of low-noise amplifiers 21 and 22 may be partially or entirely included in RFIC 3.

Filter 31 (A-Rx/B-Rx) is an example of a first filter, and is a band-pass filter having a passband (an example of a first passband) that includes the downlink band of Band A and the downlink band of Band B. Filter 31 is connected between switch 51 and low-noise amplifier 21. Specifically, one end of filter 31 is connected to terminal 512 of switch 51, and another end of filter 31 is connected to the input end of low-noise amplifier 21.

Filter 32 (A-Tx/B-Tx) is an example of a second filter, and is a band-pass filter having a passband (an example of a second passband) that includes the uplink band of Band A and the uplink band of Band B. Filter 32 is connected between switch 51 and power amplifier 11. Specifically, one end of filter 32 is connected to terminal 513 of switch 51, and another end of filter 32 is connected to the output end of power amplifier 11. Note that filter 32 may be separated into two filters (a transmission filter of Band A and a transmission filter of Band B). In such cases, radio frequency circuit 1 may include only one of the two filters, and the other of the two filters need not be included. Also, filter 32 need not be included in radio frequency circuit 1.

Filter 33 (C-Rx/D-Rx) is an example of a third filter or a fourth filter, and is a band-pass filter having a passband (an example of a third passband) that includes a downlink band of Band C and a downlink band of Band D. Filter 33 is connected between switch 51 and low-noise amplifier 22. Specifically, one end of filter 33 is connected to terminal 512 of switch 51, and another end of filter 33 is connected to the input end of low-noise amplifier 22. Note that filter 33 may be separated into two filters (a reception filter of Band C and a reception filter of Band D). In such cases, radio frequency circuit 1 may include one of the two filters, and the other of the two filters need not be included.

Filter 34 (C-Tx/D-Tx) is an example of a third filter or a fourth filter, and is a band-pass filter having a passband (an example of a fourth passband) that includes an uplink band of Band C and an uplink band of Band D. Filter 34 is connected between switch 51 and power amplifier 12. Specifically, one end of filter 34 is connected to terminal 513 of switch 51, and another end of filter 34 is connected to the output end of power amplifier 12. Note that filter 34 may be separated into two filters (a transmission filter of Band C and a transmission filter of Band D). In such cases, radio frequency circuit 1 may include only one of the two filters, and the other of the two filters need not be included.

Note that one or both of filter 33 and filter 34 need not be included in radio frequency circuit 1. In a case in which one of filter 33 or filter 34 is not included in radio frequency circuit 1, the other of filter 33 or filter 34 is an example of a third filter.

Switch 51 is connected between antenna connection terminal 100 and filters 31 to 34. Specifically, switch 51 includes terminals 511 to 513. Terminal 511 is an example of a first terminal, and is connected to antenna connection terminal 100. Terminal 512 is an example of a second terminal, and is connected to filters 31 and 33. Terminal 513 is an example of a third terminal, and is connected to filters 32 and 34.

With such a connection configuration, switch 51 can connect terminal 511 to terminals 512 and 513, based on a control signal from RFIC 3, for example. Stated differently, switch 51 can switch between connecting terminal 511 only to terminal 512, connecting terminal 511 only to terminal 513, or simultaneously connecting terminal 511 to both terminals 512 and 513. Switch 51 includes a multi-connection type switch circuit, for example.

### [1.3 Specific Example of Frequency Bands]

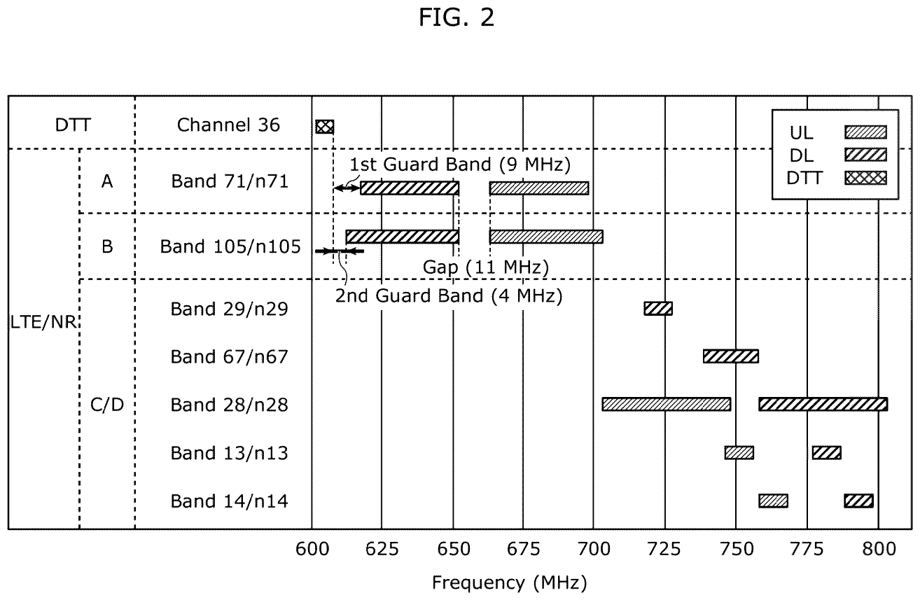

Here, a specific example of frequency bands related to communication device 5 according to the present embodiment will be described with reference to FIG. 2. FIG. 2 illustrates a specific example of frequency bands related to communication device 5 according to the present embodiment. In FIG. 2, the vertical axis shows band names, and the horizontal axis shows frequencies (MHz).

Bands A to D are frequency bands for a communication system established by using radio access technology (RAT), and are predefined by standardizing bodies (such as 3GPP and IEEE, for example). Examples of the communication system include a 5th Generation New Radio (5G NR) system, a Long Term Evolution (LTE) system, and a Wireless Local Area Network (WLAN) system.

Band A is an example of a first band and is an FDD band that includes an uplink band and a downlink band. A first guard band for the downlink band of Band A is defined on the lower frequency side of the downlink band of Band A. The first guard band separates the downlink band of Band A from the digital terrestrial television (DTT) channel.

As Band A, Band 71 for LTE or n71 for 5G NR (DL: 617 MHz to 652 MHz, UL: 663 MHz to 698 MHz) can be used. In such cases, the first guard band exists with a bandwidth of 9 MHz between the high-frequency edge of the 6 MHz DTT channel 36 (602 MHz to 608 MHz) and the low-frequency edge of the downlink band of Band 71 or n71. The frequency gap between the uplink band and the downlink band of Band A is 9 MHz.

Band B is an example of a second band and is an FDD band that includes an uplink band and a downlink band. The downlink band of Band B at least partially overlaps the downlink band of Band A. More specifically, the low-frequency edge of the downlink band of Band B is lower than the low-frequency edge of the downlink band of Band A, but the high-frequency edge of the downlink band of Band B coincides with the high-frequency edge of the downlink band of Band A. A second guard band for the downlink band of Band B is defined on the lower frequency side of the downlink band of Band B. The second guard band separates the downlink band of Band B from the DTT channel. Here, the low-frequency edge of the second guard band coincides with the low-frequency edge of the first guard band. Stated differently, guard bands for the downlink band of Band A and the downlink band of Band B are defined with respect to the same DTT channel. Therefore, the bandwidth of the second guard band is narrower than the bandwidth of the first guard band.

As Band B, Band 105 for LTE or n105 for 5G NR (DL: 612 MHz to 652 MHz, UL: 663 MHz to 703 MHz) can be used. In such cases, the second guard band exists with a bandwidth of 4 MHz between the high-frequency edge of the 6 MHz DTT channel 36 and the low-frequency edge of the downlink band of Band 105 or n105. Therefore, the bandwidth of the second guard band (4 MHz) is narrower than the frequency gap (9 MHz) between the uplink band and the downlink band of Band B.

Bands C and D are examples of a third band and a fourth band, and are FDD bands that include an uplink band and a downlink band, or supplementary downlink (SDL) bands that include only a downlink band. A combination of Bands A and C, and a combination of Bands A and D are band combinations for simultaneous communication. Note that a combination of Bands B and C may be a band combination for simultaneous communication, and a combination of Bands B and D may be a band combination for simultaneous communication.

Band 13, Band 14, Band 28, Band 29, or Band 67 for LTE or n13, n14, n28, n29, or n67 for 5G NR can be used as Bands C and D. Stated differently, one of Band 13, Band 14, Band 28, Band 29, or Band 67 for LTE, or n13, n14, n28, n29, or n67 for 5G NR can be used as Band C, and another one of Band 13, Band 14, Band 28, Band 29, or Band 67 for LTE, or n13, n14, n28, n29, or n67 for 5G NR can be used as Band D.

### [1.4 Pass Characteristic of Filters 31 and 32]

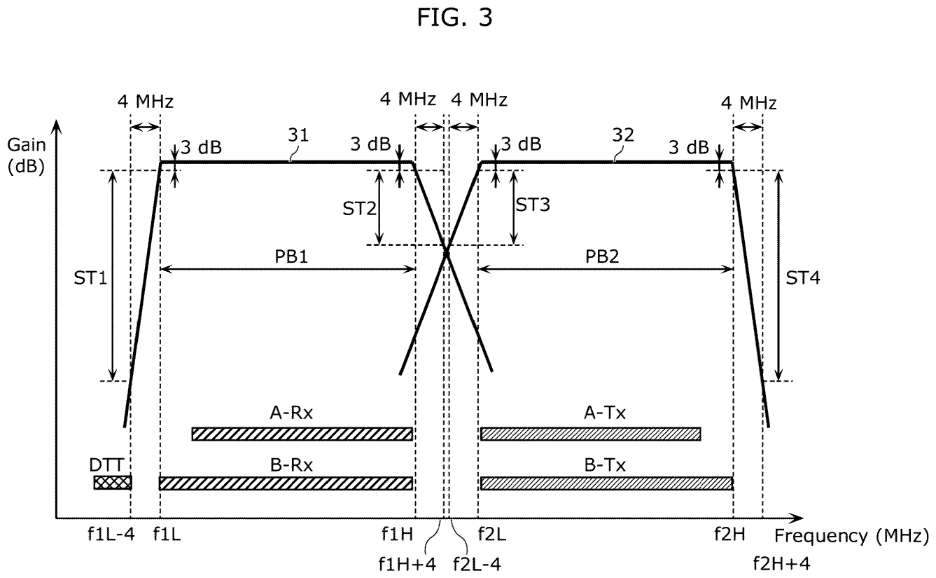

Next, the pass characteristic of filters 31 and 32 will be described with reference to FIG. 3. FIG. 3 illustrates a graph showing pass characteristics of filters 31 and 32 according to the present embodiment. In FIG. 3, frequency is shown on the horizontal axis and gain is shown on the vertical axis. As may be seen therein, both the filters 31 and 32 have an asymmetrical frequency response. This asymmetry is characterized by the filter having a significantly different cutoff or attenuation slope on a first frequency side compared to a second frequency side. This deliberate asymmetry allows the filter to meet interference requirements on one side of the passband while maintaining high performance and efficiency across the rest of the band, thereby allowing fewer filters to be used.

Passband PB1 of filter 31 is an example of a first passband, and as illustrated in FIG. 3, includes the downlink band (A-Rx) of Band A and the downlink band (B-Rx) of Band B. More specifically, low-frequency edge f1L of passband PB1 is lower than the low-frequency edge of each of the downlink bands of Bands A and B. High-frequency edge f1H of passband PB1 is higher than the high-frequency edge of each of the downlink bands of Bands A and B.

Attenuation steepness ST1 on the lower frequency side of passband PB1 of filter 31 is higher than attenuation steepness ST2 on the higher frequency side of passband PB1 of filter 31. Stated differently, the difference (=attenuation steepness ST1) between the gain at low-frequency edge f1L of passband PB1 of filter 31 and the gain at a frequency 4 MHz lower than low-frequency edge f1L (f1L−4 MHz) is greater than the difference (=attenuation steepness ST2) between the gain at high-frequency edge f1H of passband PB1 of filter 31 and the gain at a frequency 4 MHz higher than high-frequency edge f1H (f1H+4 MHz).

Passband PB2 of filter 32 is an example of a second passband, and as illustrated in FIG. 3, includes the uplink band (A-Tx) of Band A and the uplink band (B-Tx) of Band B. More specifically, low-frequency edge f2L of passband PB2 is lower than the low-frequency edge of each of the uplink bands of Bands A and B. High-frequency edge f2H of passband PB2 is higher than the high-frequency edge of each of the uplink bands of Bands A and B.

Attenuation steepness ST4 on the higher frequency side of passband PB2 of filter 32 is higher than attenuation steepness ST3 on the lower frequency side of passband PB2 of filter 32. Stated differently, the difference (=attenuation steepness ST4) between the gain at high-frequency edge f2H of passband PB2 of filter 32 and the gain at a frequency 4 MHz higher than high-frequency edge f2H (f2H+4 MHz) is greater than the difference (=attenuation steepness ST3) between the gain at low-frequency edge f2L of passband PB2 of filter 32 and the gain at a frequency 4 MHz lower than low-frequency edge f2L (f2L−4 MHz).

### [1.5 Circuit Configuration of Filters 31 and 32]

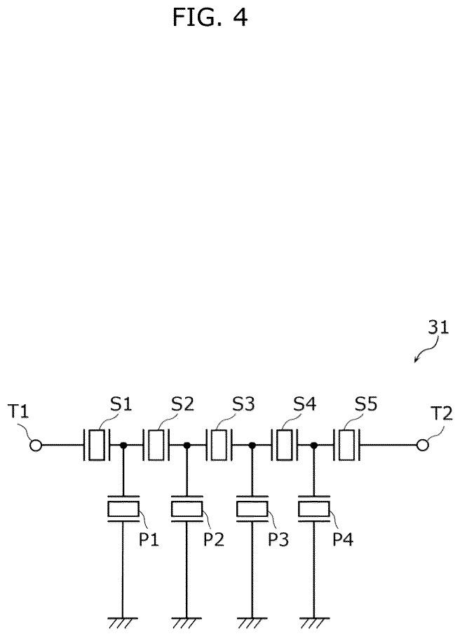

A circuit configuration of filter 31 that can achieve such pass characteristics will be described with reference to FIG. 4. Note that the circuit configuration of filter 32 is similar to the configuration of filter 31, and thus illustration and description thereof are omitted.

FIG. 4 illustrates a circuit configuration of filter 31 according to the present embodiment. Note that FIG. 4 illustrates an exemplary circuit configuration, and filter 31 may be implemented using any of various types of circuit implementations and circuit technologies. Thus, the description of filter 31 provided below should not be interpreted in a limited manner.

Filter 31 is an acoustic wave filter, and includes input-output terminals T1 and T2, series arm resonators S1 to S5, and a plurality of parallel arm resonators P1 to P4.

The plurality of series arm resonators S1 to S5 are connected in series between input-output terminals T1 and T2. The plurality of parallel arm resonators P1 to P4 are connected in parallel to each other between a path connecting input-output terminals T1 and T2 and the ground. With such a connection configuration of series arm resonators S1 to S5 and the plurality of parallel arm resonators P1 to P4, filter 31 forms a ladder-type bandpass filter. Filter 31 functions as a bandpass filter including passband PB1 and attenuation bands on the lower frequency side and the higher frequency side of passband PB1.

Note that the number of series arm resonators and the number of parallel arm resonators included in filter 31 are not limited to 5 and 4, respectively. For example, the number of series arm resonators and the number of parallel arm resonators included in filter 31 may both be 1. Stated differently, filter 31 may include at least one series arm resonator and at least one parallel arm resonator. Also, filter 31 need not be an acoustic wave filter.

### [1.6 Basic Structure of Resonators]

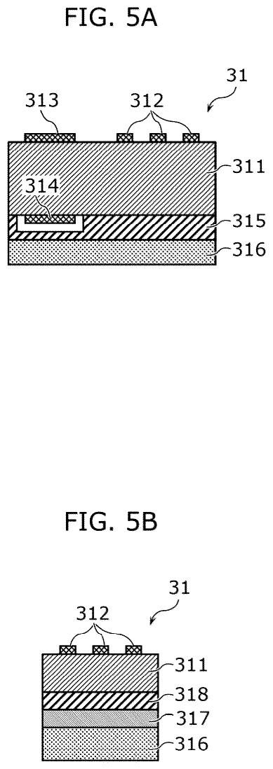

Next, the basic structure of the plurality of series arm resonators S1 to S5 and the plurality of parallel arm resonators P1 to P4 that constitute filter 31 will be described with reference to FIG. 5A. Note that the basic structure of the resonators of filter 32 is similar to the basic structure of the resonators of filter 31, and thus illustration and description thereof are omitted.

FIG. 5A illustrates a cross-sectional view of filter 31 according to the present embodiment. Filter 31 includes piezoelectric layer 311, interdigital transducer (IDT) electrodes 312, upper electrode 313, lower electrode 314, silicon dioxide layer 315, and support substrate 316.

Piezoelectric layer 311 can propagate surface acoustic waves (SAW) between IDT electrodes 312 that are formed on its main surface. Furthermore, piezoelectric layer 311 can propagate bulk acoustic waves (BAW) between upper electrode 313 and lower electrode 314. Piezoelectric layer 311 includes, for example, a piezoelectric single crystal or piezoelectric ceramics of lithium tantalate (LiTaO₃), lithium niobate (LiNbO₃), aluminum nitride (AlN), or zinc oxide (ZnO). Note that the material of piezoelectric layer 311 is not limited thereto.

IDT electrodes 312 are formed on the main surface of piezoelectric layer 311 and can generate and detect surface acoustic waves. IDT electrodes 312 include, for example, aluminum (Al), titanium (Ti), gold (Au), silver (Ag), copper (Cu), platinum (Pt), tungsten (W), molybdenum (Mo), ruthenium (Ru), or any combination thereof. Note that the material of IDT electrodes 312 is not limited thereto.

Upper electrode 313 and lower electrode 314 are formed on the upper surface and lower surface of piezoelectric layer 311, respectively, and can generate and detect bulk waves. Upper electrode 313 and lower electrode 314 include, similar to IDT electrodes 312, for example, Al, Ti, Au, Ag, Cu, Pt, W, Mo, Ru, or any combination thereof. Note that the material of upper electrode 313 and lower electrode 314 is not limited thereto.

Silicon dioxide layer 315 functions as a spacer for providing a hollow structure around lower electrode 314. More specifically, silicon dioxide layer 315 includes a recess, on the piezoelectric layer 311 side, in which lower electrode 314 is accommodated. This creates sufficient space for lower electrode 314 to vibrate.

Support substrate 316 is disposed below silicon dioxide layer 315 and piezoelectric layer 311, and can support silicon dioxide layer 315 and piezoelectric layer 311. Support substrate 316 includes silicon (Si), quartz, or sapphire, for example. Note that the material of support substrate 316 is not limited thereto.

With the basic structure of FIG. 5A, filter 31 can be realized that includes a plurality of series arm resonators S1 to S5 as surface acoustic wave (SAW) resonators, and includes a plurality of parallel arm resonators P1 to P4 as bulk acoustic wave (BAW) resonators. Note that not all of the plurality of parallel arm resonators P1 to P4 need to be BAW resonators, and it is sufficient if at least one of the plurality of parallel arm resonators P1 to P4 is a BAW resonator.

Note that the basic structure of series arm resonators and parallel arm resonators of filters 31 and 32 is not limited to the structure illustrated in FIG. 5A. For example, in filter 31 and/or filter 32, the series arm resonator and the parallel arm resonator may both be SAW resonators. In such cases, filter 31 and/or filter 32 need not include upper electrode 313, lower electrode 314, silicon dioxide layer 315, support substrate 316, or any combination thereof.

### [1.7 Advantageous Effects, Etc.]

As described above, radio frequency circuit 1 according to the present embodiment includes filter 31 having passband PB1 that includes a downlink band of Band A and a downlink band of Band B. The downlink band of Band B at least partially overlaps the downlink band of Band A. The low-frequency edge of the downlink band of Band B is lower than the low-frequency edge of the downlink band of Band A. The low-frequency edge of a first guard band defined on the lower frequency side of the downlink band of Band A coincides with the low-frequency edge of a second guard band defined on the lower frequency side of the downlink band of Band B, the first guard band being for the downlink band of Band A, and the second guard band being for the downlink band of Band B. Filter 31 has a higher attenuation steepness on the lower frequency side of passband PB1 than on the higher frequency side of passband PB1.

With this, filter 31 can be shared for the downlink band of Band A and the downlink band of Band B, which can inhibit an increase in the number of filters required for multi-band functionality. In particular, since the low-frequency edge of the downlink band of Band B is lower than the low-frequency edge of the downlink band of Band A, the bandwidth of the second guard band becomes narrower than the bandwidth of the first guard band. Under such conditions, by using filter 31 that has a higher attenuation steepness on the lower frequency side than on the higher frequency side of passband PB1, interference between (i) other bands or channels adjacent to the first guard band and the second guard band and (ii) the downlink band of Band B can be effectively inhibited, making it possible to share filter 31 for the downlink band of Band A and the downlink band of Band B.

For example, in radio frequency circuit 1 according to the present embodiment, the high-frequency edge of the downlink band of Band B may coincide with the high-frequency edge of the downlink band of Band A.

With this, the interference conditions on the higher frequency side of the downlink band of Band B match those of the higher frequency side of the downlink band of Band A. Therefore, even if the attenuation steepness on the higher frequency side of passband PB1 of filter 31 is lower than that on the lower frequency side, interference between other bands or channels higher than the downlink band of Band B and the downlink band of Band B can be inhibited.

For example, radio frequency circuit 1 according to the present embodiment may further include filter 32 having passband PB2 that includes an uplink band of Band A, and the bandwidth of the second guard band may be narrower than the frequency gap between the downlink band and the uplink band of Band A.

With this, since the bandwidth of the second guard band is narrower than the frequency gap between the downlink band and the uplink band of Band A, even when using filter 31 that has a higher attenuation steepness on the lower frequency side than on the higher frequency side of passband PB1, interference between the downlink bands of Bands A and B and other bands or channels can be inhibited.

For example, in radio frequency circuit 1 according to the present embodiment, filter 31 may be an acoustic wave filter that includes at least one series arm resonator S1 to S5 and at least one parallel arm resonator P1 to P4, the at least one series arm resonator S1 to S5 may include a SAW resonator, and the at least one parallel arm resonator P1 to P4 may include a BAW resonator.

With this, since BAW resonators are used for at least one of parallel arm resonators P1 to P4, a higher quality factor (Q value) can be achieved, and the attenuation steepness on the lower frequency side of passband PB1 can be increased.

For example, in radio frequency circuit 1 according to the present embodiment, passband PB2 of filter 32 may further include an uplink band of Band B.

With this, filter 32 can be shared for the uplink band of Band A and the uplink band of Band B, which can inhibit an increase in the number of filters required for multi-band functionality.

For example, radio frequency circuit 1 according to the present embodiment may further include filter 33 having a passband that includes an uplink band or a downlink band of Band C that is higher than the uplink band of Band A and the uplink band of Band B, the high-frequency edge of the uplink band of Band B may be higher than the high-frequency edge of the uplink band of Band A, and filter 32 may have a higher attenuation steepness on the higher frequency side of passband PB2 than on the lower frequency side of passband PB2.

With this, since the high-frequency edge of the uplink band of Band B is higher than the high-frequency edge of the uplink band of Band A, the frequency gap between the uplink band or downlink band of Band C becomes narrower. Under such conditions, by using filter 32 that has a higher attenuation steepness on the higher frequency side than on the lower frequency side of passband PB2, interference between the uplink band or downlink band of Band C and the uplink band of Band B can be effectively inhibited, making it possible to share filter 32 for the uplink band of Band A and the uplink band of Band B.

For example, in radio frequency circuit 1 according to the present embodiment, the low-frequency edge of the uplink band of Band B may coincide with the low-frequency edge of the uplink band of Band A.

With this, the interference conditions on the lower frequency side of the uplink band of Band B match those of the lower frequency side of the uplink band of Band A. Therefore, even if the attenuation steepness on the lower frequency side of passband PB2 of filter 32 is lower than that on the higher frequency side, interference between other bands or channels lower than the uplink band of Band B and the uplink band of Band B can be inhibited.

For example, in radio frequency circuit 1 according to the present embodiment, the combination of Bands A and C may be a band combination for simultaneous communication.

According to this, simultaneous communication of signals in Bands A and C can be supported.

For example, in radio frequency circuit 1 according to the present embodiment, the passband of filter 33 may further include an uplink band or a downlink band of Band D.

With this, filter 33 can be shared for the uplink band or downlink band of Band C and the uplink band or downlink band of Band D, which can inhibit an increase in the number of filters required for multi-band functionality.

For example, in radio frequency circuit 1 according to the present embodiment, the combination of Bands A and D may be a band combination for simultaneous communication.

According to this, simultaneous communication of signals in Bands A and D can be supported.

For example, in radio frequency circuit 1 according to the present embodiment, the passband of filter 33 may include the downlink band of Band C, and radio frequency circuit 1 may further include filter 34 having a passband that includes the uplink band of Band C.

According to this, simultaneous transmission and reception by FDD in Band C can be supported.

For example, in radio frequency circuit 1 according to the present embodiment, the passband of filter 33 may include the downlink band of Band D, and the passband of filter 34 may include the uplink band of Band D.

With this, filter 33 can be shared for the downlink band of Band C and the downlink band of Band D, and filter 34 can be shared for the uplink band of Band C and the uplink band of Band D. Therefore, an increase in the number of filters required for multi-band functionality can be inhibited.

For example, radio frequency circuit 1 according to the present embodiment may further include switch 51 that includes terminal 511 connected to antenna connection terminal 100, terminal 512 connected to filter 31 and filter 33, and terminal 513 connected to filter 32 and filter 34.

According to this, filters 31 and 33 are connected to the same terminal 512 of switch 51, and filters 32 and 34 are connected to the same terminal 513 of switch 51. Therefore, the number of terminals of switch 51 can be reduced compared to the case where filters 31 to 34 are individually connected to four terminals of switch 51, and the parasitic capacitance of switch 51 can be reduced.

For example, in radio frequency circuit 1 according to the present embodiment, Band A may be Band 71 for LTE or n71 for 5G NR. Band B may be Band 105 for LTE or n105 for 5G NR. Band C may be one of Band 13, Band 14, Band 28, Band 29, or Band 67 for LTE, or n13, n14, n28, n29, or n67 for 5G NR. Band D may be another one of Band 13, Band 14, Band 28, Band 29, or Band 67 for LTE, or n13, n14, n28, n29, or n67 for 5G NR.

With this, radio frequency circuit 1 can be utilized in LTE and/or 5G NR.

From another perspective, radio frequency circuit 1 according to the present embodiment includes filter 31 having passband PB1 that includes a downlink band of Band 71 for LTE or n71 for 5G NR, and a downlink band of Band 105 for LTE or n105 for 5G NR. Filter 31 has a higher attenuation steepness on the lower frequency side of passband PB1 than on the higher frequency side of passband PB1.

With this, filter 31 can be shared for the downlink band of Band 71 for LTE or n71 for 5G NR and the downlink band of Band 105 for LTE or n105 for 5G NR, which can inhibit an increase in the number of filters required for multi-band functionality. In particular, since the low-frequency edge of the downlink band of Band 105 for LTE or n105 for 5G NR is lower than the low-frequency edge of the downlink band of Band 71 for LTE or n71 for 5G NR, the bandwidth of the guard band defined on the lower frequency side of the downlink band of Band 105 for LTE or n105 for 5G NR becomes narrower. Under such conditions, by using filter 31 that has a higher attenuation steepness on the lower frequency side than on the higher frequency side of passband PB1, interference between other bands or channels lower than the downlink band of Band 105 for LTE or n105 for 5G NR and the downlink band of Band 105 for LTE or n105 for 5G NR can be effectively inhibited, making it possible to share filter 31 for the downlink band of Band 71 for LTE or n71 for 5G NR and the downlink band of Band 105 for LTE or n105 for 5G NR.

Communication device 5 according to the present embodiment includes: RFIC3 configured to process a radio frequency signal; and radio frequency circuit 1 configured to transfer the radio frequency signal between RFIC3 and antenna 2.

With this, advantageous effects equivalent to those of radio frequency circuit 1 can be realized by communication device 5. Furthermore, by reducing the number of filters in radio frequency circuit 1, the size of communication device 5 can be reduced.

### Variation

Next, a variation of Embodiment 1 will be described. In the present variation, the basic structure of the resonators of filters 31 and 32 is mainly different from that of Embodiment 1. Hereinafter, the present variation will be described with reference to the drawings, focusing on different points from Embodiment 1.

The basic structure of the plurality of series arm resonators S1 to S5 and the plurality of parallel arm resonators P1 to P4 that constitute filter 31 according to the present variation will be described with reference to FIG. 5B. Note that the basic structure of the resonator of filter 32 according to the present variation is similar to the basic structure of the resonator of filter 31 according to the present variation, and thus illustration and description thereof are omitted.

FIG. 5B illustrates a cross-sectional view of filter 31 according to the present variation. Filter 31 is a laminated SAW filter that includes piezoelectric layer 311, IDT electrodes 312, support substrate 316, high acoustic velocity layer 317, and low acoustic velocity layer 318.

Piezoelectric layer 311 is an example of a first piezoelectric layer and a second piezoelectric layer, and can propagate surface acoustic waves between IDT electrodes 312 that are formed on its main surface. Piezoelectric layer 311 includes, for example, a piezoelectric single crystal or piezoelectric ceramics of LiTaO₃, LiNbO₃, AlN, or ZnO. Note that the material of piezoelectric layer 311 is not limited thereto.

IDT electrodes 312 are formed on the main surface of piezoelectric layer 311, similarly to Embodiment 1, and can generate and detect surface acoustic waves. IDT electrodes 312 include, for example, Al, Ti, Au, Ag, Cu, Pt, W, Mo, Ru, or any combination thereof. Note that the material of IDT electrodes 312 is not limited thereto.

Support substrate 316 is disposed below high acoustic velocity layer 317, low acoustic velocity layer 318, and piezoelectric layer 311, and can support high acoustic velocity layer 317, low acoustic velocity layer 318, and piezoelectric layer 311. The velocity of a bulk wave propagating in support substrate 316 may be higher than the velocity of an acoustic wave (for example, a surface wave and a boundary wave) propagating in piezoelectric layer 311. Support substrate 316, similarly to Embodiment 1, includes Si, quartz, or sapphire, for example. Note that the material of support substrate 316 is not limited thereto.

High acoustic velocity layer 317 is an example of a first high acoustic velocity layer and a second high acoustic velocity layer, and is disposed below piezoelectric layer 311. In FIG. 5B, high acoustic velocity layer 317 is disposed between support substrate 316 and low acoustic velocity layer 318. High acoustic velocity layer 317 can confine the surface acoustic wave generated by IDT electrodes 312 to the portion where piezoelectric layer 311 and low acoustic velocity layer 318 are layered, and prevent the surface acoustic wave from leaking to layers below high acoustic velocity layer 317. The velocity of a bulk wave propagating in high acoustic velocity layer 317 is higher than the velocity of an acoustic wave such as a surface wave or a boundary wave propagating in piezoelectric layer 311. High acoustic velocity layer 317 includes, for example, aluminum nitride (AlN), silicon nitride (SiN), aluminum oxide (AIO), silicon carbide (SiC), silicon oxynitride (SiON), sapphire, or diamond. Note that the material of high acoustic velocity layer 317 is not limited thereto.

Low acoustic velocity layer 318 is disposed below piezoelectric layer 311. In FIG. 5B, low acoustic velocity layer 318 is disposed between high acoustic velocity layer 317 and piezoelectric layer 311. The velocity of a bulk wave propagating in low acoustic velocity layer 318 is lower than the velocity of an acoustic wave (for example, a surface wave and a boundary wave) propagating in piezoelectric layer 311. Since acoustic wave energy inherently has the property of concentrating in a medium with low acoustic velocity, the layered structure of low acoustic velocity layer 318 and high acoustic velocity layer 317 can effectively inhibit the surface acoustic wave generated by IDT electrodes 312 from leaking to the outside. Low acoustic velocity layer 318 includes silicon dioxide (SiO₂), for example. Note that the material of low acoustic velocity layer 318 is not limited thereto.

Note that the basic structure of series arm resonators and parallel arm resonators of filters 31 and 32 is not limited to the structure illustrated in FIG. 5B. For example, filter 31 and/or filter 32 need not include low acoustic velocity layer 318. Even in this case, the surface acoustic wave generated by IDT electrodes 312 can be inhibited from leaking to the outside. In filter 31 and/or filter 32, high acoustic velocity layer 317 and support substrate 316 may be integrated.

High acoustic velocity layer 317 and low acoustic velocity layer 318 may be a high impedance layer and a low impedance layer, respectively. The high impedance layer has a characteristic acoustic impedance higher than that of the low impedance layer. Conversely, the low impedance layer has a characteristic acoustic impedance lower than that of the high impedance layer. Even in such a case, the surface acoustic wave can be confined, and the surface acoustic wave can be inhibited from leaking to the outside.

As described above, in radio frequency circuit 1 according to the present variation, filter 31 and/or filter 32 may include piezoelectric layer 311 on which IDT electrodes 312 are formed, and high acoustic velocity layer 317 disposed below piezoelectric layer 311. Moreover, the velocity of a bulk wave propagating in high acoustic velocity layer 317 is higher than the velocity of an acoustic wave propagating in piezoelectric layer 311.

With this, a high Q value can be achieved through the confinement effect of acoustic waves within high acoustic velocity layer 317, and the attenuation steepness on the lower frequency side of passband PB1 can be increased.

### Embodiment 2

Next, Embodiment 2 will be described. The radio frequency circuit according to the present embodiment is mainly different from Embodiment 1 described above in that it includes a filter having a passband that includes an uplink band of Band C and a downlink band of Band D. Hereinafter, the present embodiment will be described with reference to the drawings, focusing on different points from Embodiment 1 above.

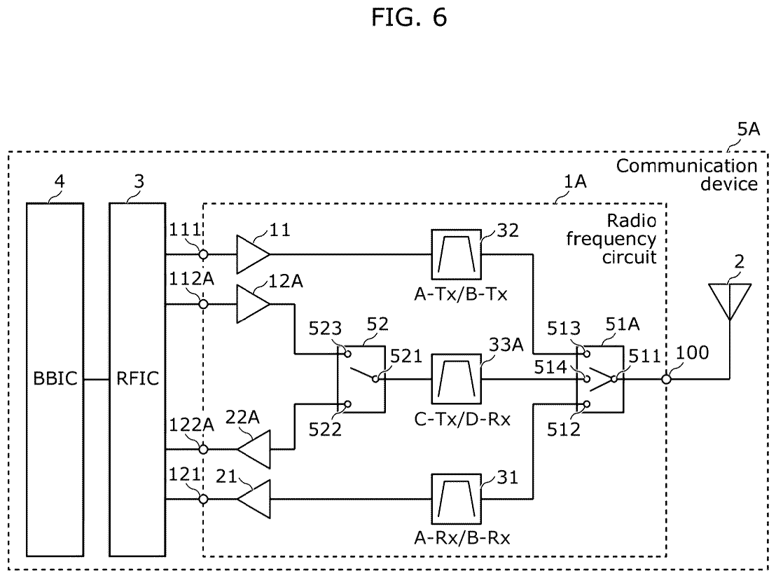

A circuit configuration of radio frequency circuit 1A according to the present embodiment will be described with reference to FIG. 6. FIG. 6 illustrates a circuit configuration of communication device 5A according to the present embodiment.

Note that FIG. 6 illustrates an exemplary circuit configuration, and communication device 5A and radio frequency circuit 1A may be implemented using any of various types of circuit implementations and circuit technologies. Thus, the description of communication device 5A and radio frequency circuit 1A provided below should not be interpreted in a limited manner.

Communication device 5A is similar to communication device 5 according to Embodiment 1 except that radio frequency circuit 1A is included instead of radio frequency circuit 1, and thus description thereof is omitted.

Radio frequency circuit 1A includes power amplifiers 11 and 12A, low-noise amplifiers 21 and 22A, filters 31, 32 and 33A, switches 51A and 52, antenna connection terminal 100, radio frequency input terminals 111 and 112A, and radio frequency output terminals 121 and 122A.

Radio frequency input terminal 112A is an external connection terminal of radio frequency circuit 1A. Specifically, radio frequency input terminal 112A is connected to RFIC 3 outside radio frequency circuit 1A and is connected to power amplifier 12A inside radio frequency circuit 1A. Radio frequency input terminal 112A can receive transmission signals in Band C from RFIC 3.

Radio frequency output terminal 122A is an external connection terminal of radio frequency circuit 1A. Specifically, radio frequency output terminal 122A is connected to RFIC 3 outside radio frequency circuit 1A and is connected to low-noise amplifier 22A inside radio frequency circuit 1A. Radio frequency output terminal 122A can supply received signals in Band D to RFIC 3.

The input end of power amplifier 12A is connected to radio frequency input terminal 112A. The output end of power amplifier 12A is connected to filter 33A via switch 52. Power amplifier 12A can amplify transmission signals in Band C received via radio frequency input terminal 112A, using power supplied from a power supply (not illustrated).

The input end of low-noise amplifier 22A is connected to filter 33A. The output end of low-noise amplifier 22A is connected to radio frequency output terminal 122A. Low-noise amplifier 22A can amplify received signals in Band D that have passed through filter 33A, by using power supplied from a power supply (not illustrated).

Filter 33A (C-Tx/D-Rx) is an example of a third filter, and is a band-pass filter having a passband (an example of a third passband) that includes an uplink band of Band C and a downlink band of Band D. Filter 33A is connected between switch 51A and switch 52. Specifically, one end of filter 33A is connected to terminal 514 of switch 51A, and another end of filter 33A is connected to terminal 521 of switch 52. Note that filter 33A may be separated into two filters (a transmission filter of Band C and a reception filter of Band D). In such cases, radio frequency circuit 1A may include one of the two filters, and the other of the two filters need not be included.

Switch 51A is connected between antenna connection terminal 100 and filters 31, 32 and 33A. Specifically, switch 51A includes terminals 511 to 514. Terminal 511 is an example of a first terminal, and is connected to antenna connection terminal 100. Terminal 512 is an example of a second terminal, and is connected to filter 31. Terminal 513 is an example of a third terminal, and is connected to filter 32. Terminal 514 is connected to filter 33A.

With such a connection configuration, switch 51A can connect terminal 511 to terminals 512 to 514, based on a control signal from RFIC 3, for example. Stated differently, switch 51A can switch between connecting terminal 511 only to terminal 512, connecting terminal 511 only to terminal 513, connecting terminal 511 only to terminal 514, or simultaneously connecting terminal 511 to any combination of terminals 512 to 514. Switch 51A includes a multi-connection type switch circuit, for example.

Switch 52 is connected between (i) filter 33A and (ii) power amplifier 12A and low-noise amplifier 22A. Specifically, switch 52 includes terminals 521 to 523. Terminal 521 is connected to filter 33A. Terminal 522 is connected to low-noise amplifier 22A. Terminal 523 is connected to power amplifier 12A.

With such a connection configuration, switch 52 can connect terminal 521 exclusively to terminal 522 or can connect terminal 521 exclusively to terminal 523, based on a control signal from RFIC 3, for example. In other words, switch 52 can switch between connecting terminal 521 only to terminal 522 or connecting terminal 521 only to terminal 523. Switch 52 includes a single-pole double-throw (SPDT) switch circuit, for example.

In the present embodiment, Band 29 for LTE or n29 for 5G NR can be used as Band C, for example, and Band 28 for LTE or n28 for 5G NR can be used as Band D, for example. Note that the combination of bands C and D is not limited thereto.

As described above, in radio frequency circuit 1A according to the present embodiment, the passband of filter 33A may include an uplink band of Band C and a downlink band of Band D.

With this, filter 33A can be shared for the uplink band of Band C and the downlink band of Band D, which can inhibit an increase in the number of filters required for multi-band functionality.

For example, Band C may be Band 29 for LTE or n29 for 5G NR, and Band D may be Band 28 for LTE or n28 for 5G NR.

With this, radio frequency circuit 1A can be utilized in LTE and/or 5G NR.

### Embodiment 3

Next, Embodiment 3 will be described. The radio frequency circuit according to the present embodiment is mainly different from Embodiment 1 described above in that three filters are connected to one terminal of a switch. Hereinafter, the present embodiment will be described with reference to the drawings, focusing on different points from Embodiment 1 above.

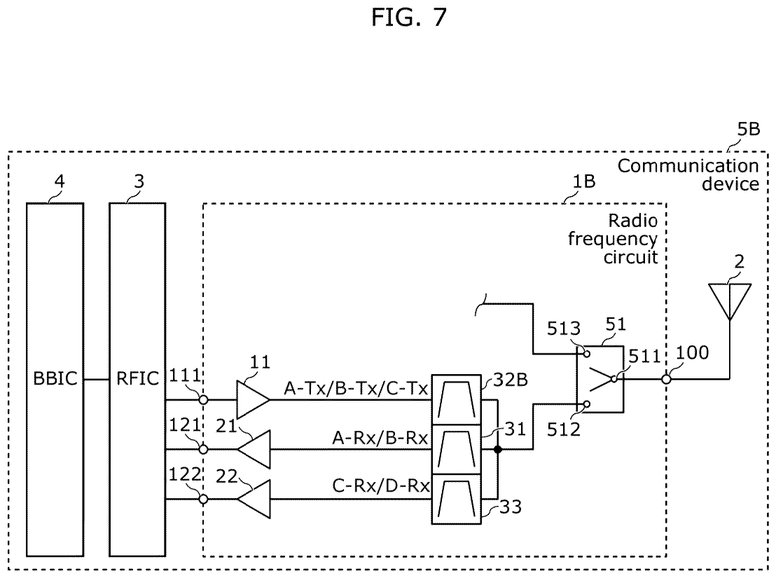

A circuit configuration of radio frequency circuit 1B according to the present embodiment will be described with reference to FIG. 7. FIG. 7 illustrates a circuit configuration of communication device 5B according to the present embodiment.

Note that FIG. 7 illustrates an exemplary circuit configuration, and communication device 5B and radio frequency circuit 1B may be mounted using any of various types of circuit implementations and circuit technologies. Thus, the description of communication device 5B and radio frequency circuit 1B provided below should not be interpreted in a limited manner.

Communication device 5B is similar to communication device 5 according to Embodiment 1 except that radio frequency circuit 1B is included instead of radio frequency circuit 1, and thus description thereof is omitted.

Radio frequency circuit 1B includes power amplifiers 11 and 12, low-noise amplifiers 21 and 22, filters 31, 32B and 33, switch 51, antenna connection terminal 100, radio frequency input terminal 111, and radio frequency output terminals 121 and 122.

Filter 32B (A-Tx/B-Tx/C-Tx) is an example of a second filter, and is a band-pass filter having a passband (an example of a second passband) that includes the uplink band of Band A, the uplink band of Band B, and the uplink band of Band C. One end of filter 32B is connected to terminal 512 of switch 51, and another end of filter 32B is connected to the output end of power amplifier 11.

As an example of a combination of Bands A to D, the following can be cited.
Band A: Band 71 for LTE or n71 for 5G NR
Band B: Band 105 for LTE or n105 for 5G NR
Band C: Band 28 for LTE or n28 for 5G NR
Band D: Band 20 for LTE or n20 for 5G NR (DL: 791 MHz to 821 MHz, UL: 832 MHz to 862 MHz)

The passband of filter 33 need not include a downlink band of Band D. In this case, as Band C, Band 12 for LTE or n12 for 5G NR (DL: 729 MHz to 746 MHz, UL: 699 MHz to 716 MHz) may be used.

### Other Embodiments

The above has described a radio frequency circuit and a communication device according to one aspect of the present disclosure, based on the embodiments, yet the radio frequency circuit and the communication device according to the present disclosure are not limited to the above embodiments. The present disclosure also encompasses another embodiment achieved by combining arbitrary elements in the above embodiments, variations resulting from applying, to the embodiments, various modifications that may be conceived by those skilled in the art within a range that does not depart from the scope of the present disclosure, and various devices that each include the radio frequency circuit.

For example, in the circuit configurations of the radio frequency circuits according to the above embodiments, another circuit element and a line, for instance, may be provided between circuit elements and paths connecting signal paths, which are disclosed in the drawings. For example, an impedance matching circuit may be provided between a power amplifier and/or a low-noise amplifier and a filter. Furthermore, for example, an impedance matching circuit may be provided between a filter and an antenna connection terminal. An impedance matching circuit can be provided with an inductor and/or a capacitor, for example, but is not limited to such a configuration.

<1>

A radio frequency circuit including:
a first filter having a first passband that includes a downlink band of a first band and a downlink band of a second band, wherein
the downlink band of the second band at least partially overlaps the downlink band of the first band,
a low-frequency edge of the downlink band of the second band is lower than a low-frequency edge of the downlink band of the first band,
a low-frequency edge of a first guard band defined on a lower frequency side of the downlink band of the first band coincides with a low-frequency edge of a second guard band defined on a lower frequency side of the downlink band of the second band, the first guard band being for the downlink band of the first band, and the second guard band being for the downlink band of the second band, and
the first filter has a higher attenuation steepness on a lower frequency side of the first passband than on a higher frequency side of the first passband.
   <2>

The radio frequency circuit according to <1>, wherein
a high-frequency edge of the downlink band of the second band coincides with a high-frequency edge of the downlink band of the first band.
   <3>

The radio frequency circuit according to <2>, further including:

a second filter having a second passband that includes an uplink band of the first band, wherein
a bandwidth of the second guard band is narrower than a frequency gap between the downlink band and the uplink band of the first band.
   <4>

The radio frequency circuit according to <3>, wherein
the first filter is an acoustic wave filter that includes at least one series arm resonator and at least one parallel arm resonator,
the at least one series arm resonator includes a surface acoustic wave (SAW) resonator, and
the at least one parallel arm resonator includes a bulk acoustic wave (BAW) resonator.
   <5>

The radio frequency circuit according to <3>, wherein
the first filter includes:
   a first piezoelectric layer on which an interdigital transducer (IDT) electrode is provided; and
   a first high acoustic velocity layer disposed below the first piezoelectric layer, wherein a velocity of a bulk wave propagating in the first high acoustic velocity layer is higher than a velocity of an acoustic wave propagating in the first piezoelectric layer.
      <6>

The radio frequency circuit according to any one of <3> to <5>, wherein
the second passband of the second filter further includes an uplink band of the second band.
   <7>

The radio frequency circuit according to <6>, further including:
a third filter having a third passband that includes an uplink band or a downlink band of a third band that is higher than the uplink band of the first band and the uplink band of the second band, wherein
a high-frequency edge of the uplink band of the second band is higher than a high-frequency edge of the uplink band of the first band, and
the second filter has a higher attenuation steepness on a higher frequency side of the second passband than on a lower frequency side of the second passband.
   <8>

The radio frequency circuit according to <7>, wherein
a low-frequency edge of the uplink band of the second band coincides with a low-frequency edge of the uplink band of the first band.
   <9>

The radio frequency circuit according to <8>, wherein
the second filter includes:
   a second piezoelectric layer on which an interdigital transducer (IDT) electrode is provided; and
   a second high acoustic velocity layer disposed below the second piezoelectric layer, wherein a velocity of a bulk wave propagating in the second high acoustic velocity layer is higher than a velocity of an acoustic wave propagating in the second piezoelectric layer.
      <10>

The radio frequency circuit according to any one of <7> to <9>, wherein
a combination of the first band and the third band is a band combination for simultaneous communication.
   <11>

The radio frequency circuit according to <10>, wherein
the third passband of the third filter further includes an uplink band or a downlink band of a fourth band.
   <12>

The radio frequency circuit according to <11>, wherein
a combination of the first band and the fourth band is a band combination for simultaneous communication.
   <13>

The radio frequency circuit according to <12>, wherein
the third passband of the third filter includes the downlink band of the third band, and
the radio frequency circuit further includes a fourth filter having a fourth passband that includes the uplink band of the third band.
   <14>

The radio frequency circuit according to <13>, wherein
the third passband of the third filter includes the downlink band of the fourth band, and
the fourth passband of the fourth filter includes the uplink band of the fourth band.
   <15>

The radio frequency circuit according to <14>, further including:
a switch that includes a first terminal connected to an antenna connection terminal, a second terminal connected to the first filter and the third filter, and a third terminal connected to the second filter and the fourth filter.
   <16>

The radio frequency circuit according to any one of <1> to <6>, wherein
the first band is Band 71 for LTE or n71 for 5G NR, and
the second band is Band 105 for LTE or n105 for 5G NR.
   <17>

The radio frequency circuit according to any one of <7> to <10>, wherein
the first band is Band 71 for LTE or n71 for 5G NR,
the second band is Band 105 for LTE or n105 for 5G NR, and
the third band is one of Band 13, Band 14, Band 28, Band 29, or Band 67 for LTE, or n13, n14, n28, n29, or n67 for 5G NR.
   <18>

The radio frequency circuit according to any one of <11> to <15>, wherein
the first band is Band 71 for LTE or n71 for 5G NR,
the second band is Band 105 for LTE or n105 for 5G NR,
the third band is one of Band 13, Band 14, Band 28, Band 29, or Band 67 for LTE, or n13, n14, n28, n29, or n67 for 5G NR, and
the fourth band is another one of Band 13, Band 14, Band 28, Band 29, or Band 67 for LTE, or n13, n14, n28, n29, or n67 for 5G NR.
   <19>

A radio frequency circuit including:
a filter having a passband that includes a downlink band of Band 71 for LTE or n71 for 5G NR, and a downlink band of Band 105 for LTE or n105 for 5G NR, wherein
the filter has a higher attenuation steepness on a lower frequency side of the passband than on a higher frequency side of the passband.
   <20>

A communication device including:
a signal processing circuit configured to process a radio frequency signal; and
the radio frequency circuit according to any one of <1> to <19> configured to transfer the radio frequency signal between the signal processing circuit and an antenna.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is widely applicable to communication devices such as mobile phones as a radio frequency circuit disposed in the front-end portion.

1. A radio frequency circuit comprising:
a first filter having a first passband that includes a downlink band of a first band and a downlink band of a second band, wherein
the downlink band of the second band at least partially overlaps the downlink band of the first band,
a low-frequency edge of the downlink band of the second band is lower than a low-frequency edge of the downlink band of the first band,
a low-frequency edge of a first guard band defined on a lower frequency side of the downlink band of the first band coincides with a low-frequency edge of a second guard band defined on a lower frequency side of the downlink band of the second band, the first guard band being for the downlink band of the first band, and the second guard band being for the downlink band of the second band, and
the first filter has a higher attenuation steepness on a lower frequency side of the first passband than on a higher frequency side of the first passband.

2. The radio frequency circuit according to claim 1, wherein
a high-frequency edge of the downlink band of the second band coincides with a high-frequency edge of the downlink band of the first band.

3. The radio frequency circuit according to claim 2, further comprising:
a second filter having a second passband that includes an uplink band of the first band, wherein
a bandwidth of the second guard band is narrower than a frequency gap between the downlink band and the uplink band of the first band.

4. The radio frequency circuit according to claim 3, wherein
the first filter is an acoustic wave filter that includes at least one series arm resonator and at least one parallel arm resonator,
the at least one series arm resonator includes a surface acoustic wave (SAW) resonator, and
the at least one parallel arm resonator includes a bulk acoustic wave (BAW) resonator.

5. The radio frequency circuit according to claim 3, wherein
the first filter includes:
a first piezoelectric layer on which an interdigital transducer (IDT) electrode is provided; and
a first high acoustic velocity layer disposed below the first piezoelectric layer, wherein a velocity of a bulk wave propagating in the first high acoustic velocity layer is higher than a velocity of an acoustic wave propagating in the first piezoelectric layer.

6. The radio frequency circuit according to claim 3, wherein
the second passband of the second filter further includes an uplink band of the second band.

7. The radio frequency circuit according to claim 6, further comprising:
a third filter having a third passband that includes an uplink band or a downlink band of a third band that is higher than the uplink band of the first band and the uplink band of the second band, wherein
a high-frequency edge of the uplink band of the second band is higher than a high-frequency edge of the uplink band of the first band, and
the second filter has a higher attenuation steepness on a higher frequency side of the second passband than on a lower frequency side of the second passband.

8. The radio frequency circuit according to claim 7, wherein
a low-frequency edge of the uplink band of the second band coincides with a low-frequency edge of the uplink band of the first band.

9. The radio frequency circuit according to claim 8, wherein
the second filter includes:
a second piezoelectric layer on which an interdigital transducer (IDT) electrode is provided; and
a second high acoustic velocity layer disposed below the second piezoelectric layer, wherein a velocity of a bulk wave propagating in the second high acoustic velocity layer is higher than a velocity of an acoustic wave propagating in the second piezoelectric layer.

10. The radio frequency circuit according to claim 7, wherein
a combination of the first band and the third band is a band combination for simultaneous communication.

11. The radio frequency circuit according to claim 10, wherein
the third passband of the third filter further includes an uplink band or a downlink band of a fourth band.

12. The radio frequency circuit according to claim 11, wherein
a combination of the first band and the fourth band is a band combination for simultaneous communication.

13. The radio frequency circuit according to claim 12, wherein
the third passband of the third filter includes the downlink band of the third band, and
the radio frequency circuit further comprises a fourth filter having a fourth passband that includes the uplink band of the third band.

14. The radio frequency circuit according to claim 13, wherein
the third passband of the third filter includes the downlink band of the fourth band, and
the fourth passband of the fourth filter includes the uplink band of the fourth band.

15. The radio frequency circuit according to claim 14, further comprising:
a switch that includes a first terminal connected to an antenna connection terminal, a second terminal connected to the first filter and the third filter, and a third terminal connected to the second filter and the fourth filter.

16. The radio frequency circuit according to claim 1, wherein
the first band is Band 71 for LTE or n71 for 5G NR, and
the second band is Band 105 for LTE or n105 for 5G NR.

17. The radio frequency circuit according to claim 7, wherein
the first band is Band 71 for LTE or n71 for 5G NR,
the second band is Band 105 for LTE or n105 for 5G NR, and
the third band is one of Band 13, Band 14, Band 28, Band 29, or Band 67 for LTE, or n13, n14, n28, n29, or n67 for 5G NR.

18. The radio frequency circuit according to claim 11, wherein
the first band is Band 71 for LTE or n71 for 5G NR,
the second band is Band 105 for LTE or n105 for 5G NR,
the third band is one of Band 13, Band 14, Band 28, Band 29, or Band 67 for LTE, or n13, n14, n28, n29, or n67 for 5G NR, and
the fourth band is another one of Band 13, Band 14, Band 28, Band 29, or Band 67 for LTE, or n13, n14, n28, n29, or n67 for 5G NR.

19. A radio frequency circuit comprising:
a filter having a passband that includes a downlink band of Band 71 for LTE or n71 for 5G NR, and a downlink band of Band 105 for LTE or n105 for 5G NR, wherein
the filter has a higher attenuation steepness on a lower frequency side of the passband than on a higher frequency side of the passband.

20. A radio frequency circuit comprising:
a filter having a passband that selectively passes signals within a first frequency band and a second frequency band, the first and second frequency bands having at least partially overlapping downlink bands, wherein
the filter has a first attenuation slope on a first frequency side of the passband and a second attenuation slope on a second side of the passband, the first attenuation slope being steeper than the second attenuation slope.
